(19) United States
(12) Patent Application Publication
(10) Pub. No.: US 2025/0336999 A1
(43) Pub. Date: Oct. 30, 2025

(54) POWER GENERATION ELEMENT, POWER GENERATION APPARATUS, AND POWER GENERATION METHOD

(71) Applicant: Panasonic Intellectual Property Management Co., Ltd., Osaka (JP)

(72) Inventor: HYUNJEONG NAM, Nara (JP)

(21) Appl. No.: 19/260,693

(22) Filed: Jul. 7, 2025

Related U.S. Application Data
(63) Continuation of application No. PCT/JP2024/001457, filed on Jan. 19, 2024.

(30) Foreign Application Priority Data
Jan. 26, 2023 (JP) 2023-010097
Oct. 17, 2023 (JP) 2023-178981

(51) Int. Cl. H01M 8/18; H01M 4/90; H01M 8/1246

(52) U.S. Cl. CPC H01M 8/182; H01M 8/1246; H01M 4/9058; H01M 2300/0074

(57) ABSTRACT

The present disclosure provides a novel power generation element that is advantageous from the viewpoint of being maintenance-free. A power generation element according to the present disclosure includes a first electrode, a second electrode, and an inorganic solid electrolyte. The first electrode splits water. The inorganic solid electrolyte is disposed between the first electrode and the second electrode. Ions generated by the splitting of water at the first electrode are conducted through the inorganic solid electrolyte toward the second electrode. The inorganic solid electrolyte contains at least one selected from the group consisting of a water molecule and a hydroxide ion.

### BACKGROUND

### 1. Technical Field

The present disclosure relates to a power generation element, a power generation apparatus, and a power generation method.

### 2. Description of the Related Art

A thermo-electrochemical cell is known in the related art as power generation using an electrochemical reaction.

For example, International Publication No. 2018/079325 describes a thermo-electrochemical cell that can generate power when there is a temperature difference between a pair of electrodes. In this thermo-electrochemical cell, the pair of electrodes are joined to both ends of an electrolyte. At least one of the pair of electrodes is a thin film electrode formed of a conductive polymer material. This thermo-electrochemical cell can generate power due to a redox reaction near the joint surfaces of the electrolyte with the pair of electrodes when there is a temperature difference between the pair of electrodes. As the electrolyte, for example, an aqueous mixture solution of K₃[Fe(CN)₆] and K₄[Fe(CN)₆]·3 H₂O is used.

International Publication No. 2017/155046 describes a thermoelectric conversion material having a redox couple and a capturing compound. The capturing compound selectively captures only one of the redox couple at a low temperature and releases it at a high temperature. The capturing compound is at least one compound selected from the group consisting of a cyclic compound and a spiral compound. This thermoelectric conversion material is prepared as, for example, an aqueous solution.

Hongyao Zhou and Ping Liu, “High Seebeck Coefficient Electrochemical Thermocells for Efficient Waste Heat Recovery”, ACS Appl. Energy Mater. 1 (2018) 1424-1428 describes an electrochemical thermocell involving a redox reaction of acetone and isopropanol. When the temperature of a high-temperature side electrode of this electrochemical thermocell becomes higher than or equal to the boiling point of acetone, acetone vaporizes and flows toward the low-temperature side. Due to this reaction, a Seebeck coefficient as high as −9.9 mV/K is achieved.

### SUMMARY

The techniques described in the above literature involve use of liquids and can thus cause problems accompanying leakage, loss, and drying of liquids during use. These problems can cause restrictions on use such as a decrease in efficiency accompanying a decrease in power generation performance, a need for maintenance such as replacement of a thermo-electrochemical cell, and danger accompanying leakage of liquids.

One non-limiting and exemplary embodiment provides a novel power generation element that has fewer restrictions on use and that is advantageous from the viewpoint of being maintenance-free.

In one general aspect, the techniques disclosed here feature a power generation element including a first electrode that splits water, a second electrode, and an inorganic solid electrolyte that is disposed between the first electrode and the second electrode and through which ions generated by the splitting of water at the first electrode are conducted toward the second electrode, wherein the inorganic solid electrolyte contains at least one selected from the group consisting of a water molecule and a hydroxide ion.

The present disclosure can provide a novel power generation element that has fewer restrictions on use and that is advantageous from the viewpoint of being maintenance-free.

### BRIEF DESCRIPTION OF THE DRAWINGS

FIG. 1 is a diagram schematically illustrating an example of a power generation element of the present disclosure and its power generation principle;

FIG. 2 is a diagram schematically illustrating an example of a thermo-electrochemical cell;

FIG. 3 is an exploded perspective view schematically illustrating an example of a power generation apparatus of the present disclosure;

FIG. 4 is an exploded perspective view schematically illustrating another example of the power generation apparatus of the present disclosure;

FIG. 5 is a diagram schematically illustrating a measurement apparatus in examples;

FIG. 6 is a graph of a measurement result of proton conductivity of saponite;

FIG. 7 is graph of the relation between electromotive force of a power generation element according to Sample A-1 and temperature;

FIG. 8 is a diagram schematically illustrating another measurement apparatus in examples;

FIG. 9 is a graph of I-V characteristics of the power generation element according to Sample A-1;

FIG. 10 is a graph of continuous discharge characteristics of the power generation element according to Sample A-1;

FIG. 11 is a graph of I-V characteristics of a power generation element according to Sample B-3; and

FIG. 12 is a graph of continuous discharge characteristics of the power generation element according to Sample B-3.

### DETAILED DESCRIPTIONS

### Underlying Knowledge Forming Basis of the Present Disclosure

From the viewpoint of lower CO₂ emissions, zero carbon, and carbon neutral, efficient use of energy is required. It is contemplated to effectively use unused heat generated from plants, automobiles, and living environments, and techniques for utilizing such unused heat are also addressed as national projects and can become important techniques in the future society. For example, to effectively use unused heat by converting it into electric energy, devices in a field called energy harvesting are expected to become widespread.

Devices that convert heat into electric energy include thermoelectric conversion elements or thermo-electrochemical cells using physical phenomena such as the Seebeck effect. Some thermoelectric conversion elements have already been commercialized. However, to convert heat into electric energy using a thermoelectric conversion element, a predetermined temperature difference is required to be generated between both ends of the thermoelectric conversion element. Meanwhile, thermo-electrochemical cells are used only in specific applications such as waste heat recovery for rockets and sodium-sulfur batteries, and further technical developments are required from the viewpoint of utilization of unused heat. When an electrolyte solution is used as an electrolyte in a thermo-electrochemical cell, there is a possibility of a decrease in the amount of the electrolyte solution and a leakage of the electrolyte solution accompanying supply of heat to the thermo-electrochemical cell, and predetermined maintenance will be required. Meanwhile, for example, if a device that converts heat into electric energy and that can be disposed at places in which maintenance is not easy, such as enclosed spaces, chimneys of plants, and plant equipment, can be provided, utilization of unused heat will be further promoted.

Accordingly, the present inventor has made intensive studies to provide a novel power generation element that has fewer restrictions on use and that is maintenance-free. The present inventor has newly found that an element that can generate power using water, which can be widely present in the environment, can be constructed. To construct an element that is maintenance-free and that can generate power using water in the environment, a solid ion conductor is important. In recent years, various kinds of solid proton conductors have been reported. However, most inorganic solid proton conductors exhibit decreased ionic conductivity with decreasing temperature, and few materials that show high ionic conductivity at a temperature lower than or equal to 200° C. are known. Meanwhile, the present inventor has focused on the fact that inorganic substances such as smectite may have ionic conductivity even at low temperatures, although they are not widely known as ion conductors. The present inventor has conducted trial and error to construct an element that is maintenance-free and that can generate power using water in the environment by using predetermined inorganic substances such as minerals, which are materials that are widely distributed on the earth, nontoxic to human bodies, and inexpensive, as an electrolyte. Consequently, the present inventor has newly found that such an element can be obtained by using a predetermined inorganic solid electrolyte. Based on this new knowledge, the present inventor has completed a power generation element according to the present disclosure.

### Embodiment of Present Disclosure

An embodiment of the present disclosure will be described below with reference to the drawings.

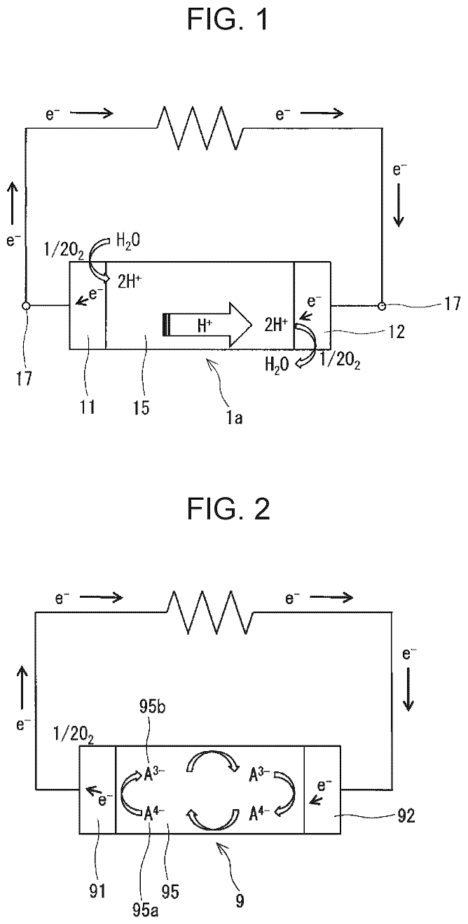

FIG. 1 is a diagram schematically illustrating an example of a power generation element of the present disclosure and its power generation principle. As illustrated in FIG. 1, a power generation element 1a includes a first electrode 11, a second electrode 12, and an inorganic solid electrolyte 15. The power generation element 1a is a power generation element all of which is formed of solids. The first electrode 11 splits water. Water can be present in liquid phase or gas phase in an environment adjoining the first electrode 11. When water comes into contact with the first electrode 11, the water is split to generate certain ions. The inorganic solid electrolyte 15 is disposed between the first electrode 11 and the second electrode 12. The inorganic solid electrolyte 15 may be in direct contact with the first electrode 11, or a catalyst may be disposed between the inorganic solid electrolyte 15 and the first electrode 11. The inorganic solid electrolyte 15 may be in direct contact with the second electrode 12, or a catalyst may be disposed between the inorganic solid electrolyte 15 and the second electrode 12. Ions generated by the splitting of water at the first electrode 11 are conducted through the inorganic solid electrolyte 15 toward the second electrode 12. The inorganic solid electrolyte 15 contains at least one selected from the group consisting of a water molecule and a hydroxide ion. The splitting of water at the first electrode 11 and the generation of ions in the inorganic solid electrolyte 15 cause a potential difference between the first electrode 11 and the second electrode 12, causing a current due to the conduction of ions. This causes the power generation element 1a to supply electric energy outside the power generation element 1a.

FIG. 2 is a diagram schematically illustrating an example of a thermo-electrochemical cell. As illustrated in FIG. 2, a thermo-electrochemical cell 9 includes an electrode 91, an electrode 92, and an electrolyte solution 95. The electrode 91 is an electrode that oxidizes an electrolyte at a high temperature, and the electrode 92 is an electrode that reduces the electrolyte at a low temperature. The electrolyte solution 95 contains a first ion 95a and a second ion 95b, and the first ion 95a and the second ion 95b have different valence numbers from each other. For example, the first ion 95a is oxidized at the electrode 91 to change to the second ion 95b. The second ion 95b is reduced at the electrode 92 to change to the first ion 95a. When predetermined heat is supplied to the thermo-electrochemical cell 9, and for example, the electrode 91 is at a high temperature, the electrode 91 oxidizes the first ion 95a contained in the electrolyte solution 95 to produce the second ion 95b, and an electron is given to the electrode 91. Meanwhile, the electrode 92 receives the electron passing through an external circuit connected to the thermo-electrochemical cell 9 and reduces the second ion 95b contained in the electrolyte solution 95 to produce the first ion 95a. In the electrolyte solution 95, due to convection and diffusion, the first ion 95a moves toward the electrode 91, while the second ion 95b moves toward the electrode 92. Consequently, a redox reaction involving the first ion 95a and the second ion 95b continuously occurs, producing a current in the external circuit. An electromotive force corresponding to a difference in redox potential at a specific temperature between the electrode 91 and the electrode 92 is produced, producing a current from the electrode 91 having a high redox potential to the electrode 92 having a low redox potential. In this case, thermal energy supplied to the thermo-electrochemical cell 9 is consumed for the redox reaction and the diffusion of the ions, with its surplus being taken out as electric energy.

The thermo-electrochemical cell 9 includes the electrolyte solution 95, and when heat is supplied to the thermo-electrochemical cell 9, the solvent of the electrolyte solution 95 may evaporate, and the amount of the electrolyte solution 95 may decrease. In addition, the electrolyte solution 95 may leak from the thermo-electrochemical cell 9. Thus, the thermo-electrochemical cell 9 requires predetermined maintenance. Meanwhile, the power generation element 1a can generate power through contact between a fluid containing water present outside the power generation element 1a and the first electrode 11. Thus, so long as water is present in the environment adjoining the first electrode 11, power can be generated. For example, since a certain amount of water can inevitably be present in air, the power generation element 1a can generate power using such water. In addition, in the power generation element 1a, since ions generated by the splitting of water using the solid electrolyte are conducted, neither a decrease in the amount of the electrolyte solution nor a leakage of the electrolyte solution occurs. Thus, the power generation element 1a has fewer restrictions on use and that is advantageous from the viewpoint of being maintenance-free.

As described above, the inorganic solid electrolyte 15 shows ionic conductivity for ions generated by the splitting of water. The inorganic solid electrolyte 15 has ionic conductivity for, for example, one kind of ion selected from the group consisting of a proton, an oxide ion, a hydronium ion, and a hydroxide ion. In the example illustrated in FIG. 1, the inorganic solid electrolyte 15 has proton conductivity. The inorganic solid electrolyte 15 contains at least one selected from the group consisting of a water molecule and a hydroxide ion and thus tends to have high ionic conductivity during power generation by the power generation element 1a.

The power generation element 1a will be described in more detail by taking as an example a case in which protons are conducted through the inorganic solid electrolyte 15. For example, catalytic activity for water splitting by the first electrode 11 at a predetermined temperature is higher than catalytic activity for water splitting by the second electrode 12 at the predetermined temperature. In this case, the material of the first electrode 11 is, for example, different from the material of the second electrode 12. For example, heat can be supplied to the entire power generation element 1a so that no temperature difference occurs between the first electrode 11 and the second electrode 12. In this case, due to the difference in catalytic activity for water splitting between the first electrode 11 and the second electrode 12, the concentration of protons generated at the first electrode 11 is higher than the concentration of protons generated at the second electrode 12. Heat may be supplied to the power generation element 1a such that the temperature of the first electrode 11 is higher than the temperature of the second electrode 12. Also in this case, due to the difference in catalytic activity for water splitting between the first electrode 11 and the second electrode 12, the concentration of protons generated at the first electrode 11 is higher than the concentration of protons generated at the second electrode 12.

The material of the first electrode 11 may be the same as the material of the second electrode 12. In this case, heat can be supplied to the power generation element 1a such that the temperature of the first electrode 11 is higher than the temperature of the second electrode 12. Heat may be supplied to the entire power generation element 1a so that no temperature difference occurs between the first electrode 11 and the second electrode 12, and the power generation element 1a may be placed in an environment in which the concentration of water supplied to the first electrode 11 is higher than the concentration of water supplied to the second electrode 12. Also in these cases, the concentration of protons generated at the first electrode 11 is higher than the concentration of protons generated at the second electrode 12.

Due to such a difference in proton concentration between the first electrode 11 and the second electrode 12, an electromotive force E based on Equation (3) below, which is the Nernst equation, is generated. Protons diffuse by heat and the concentration difference in the inorganic solid electrolyte 15, and protons and oxygen react with each other at the second electrode 12 to generate water vapor. This water vapor diffuses outside the power generation element 1a. An electromotive force accompanying a difference in ionic activity is generated between the first electrode 11 and the second electrode 12, and electrons move through the external circuit of the power generation element 1a. The heat supplied to the power generation element 1a is consumed for the splitting of water at the first electrode 11 and the diffusion of protons in the inorganic solid electrolyte 15. Excess chemical energy accompanying the generation of water at the second electrode 12 is taken out as electric energy.

According to the first law of thermodynamics, the extracted free energy G is defined as in Equation (1) using enthalpy H, thermodynamic temperature T, and entropy S.

G=H−TS Equation (1)

The relation between the free energy G to be taken out and the electromotive force accompanying a battery reaction is represented by Equation (2). In Equation (2), n is the number of moles reacted, E₀ is a standard electromotive force, and F is the Faraday constant, namely, 96,485 Cmol⁻¹.

ΔG₀=−nE₀F Equation (2)

When the ionic activity in an oxidized state and the ionic activity in a reduced state in a redox reaction are represented as a_{Ox} and a_{Red}, respectively, the Nernst equation, or Equation (3), is obtained. In Equation (3), E⁰ is a standard electrode potential, R is the gas constant, namely, 8.31 JK⁻¹ mol⁻¹, T is absolute temperature, z is the number of electrons moved, and F is the Faraday constant.

E=E⁰+(RT/zF)In(a_{Ox}/a_{Red}) Equation (3)

The power generation element 1a can also generate power using water present in the environment adjoining the first electrode 11 when ions other than protons generated by the splitting of water are conducted through the inorganic solid electrolyte 15.

Thus, the power generation element 1a is a new power generation element that combines a thermodynamic phenomenon with an electrochemical principle and that uses water present in the environment in which the power generation element 1a is placed as an electrolyte source. The power generation element 1a can produce electric energy, for example, even when there is no temperature difference required in the Seebeck effect or the like. As described above, the power generation element 1a can have Configuration A, in which catalytic activity for water splitting by the first electrode 11 at a predetermined temperature is higher than catalytic activity for water splitting by the second electrode 12 at the predetermined temperature. The power generation element 1a may have Configuration B, in which the first electrode 11 and the second electrode 12 are formed of the same material as each other. When the power generation element 1a has Configuration A, the power generation element 1a can generate power even when the water vapor concentration around the power generation element 1a is uniform. When the power generation element 1a has Configuration B, the power generation element 1a can generate power, for example, as heat is supplied to the power generation element 1a such that the temperature of the first electrode 11 is higher than the temperature of the second electrode 12. In addition, when the power generation element 1a has Configuration B, the power generation element 1a can also generate power when the concentration of water supplied to the first electrode 11 is higher than the concentration of water supplied to the second electrode 12.

The water used for the splitting of water at the first electrode 11 of the power generation element 1a may be water contained in air, water present in an enclosed space, or water derived from humidified air supplied from the outside.

The power generation element 1a can be used to provide, for example, a power generation method including (I), (II), (III), and (IV):

(I) placing the power generation element 1a in an environment in which water is present to split water by the first electrode 11 and generate ions;
(II) conducting the ions generated in (I) toward the second electrode 12 in the inorganic solid electrolyte 15;
(III) oxidizing or reducing the ions generated in (I) at the second electrode 12 to generate water; and
(IV) generating a current outside the power generation element 1a.

In the power generation method, for example, heat at a temperature lower than or equal to 300° C. is supplied to the power generation element 1a. The temperature of the heat to be supplied to the power generation element 1a may be lower than or equal to 250° C., lower than or equal to 200° C., or lower than or equal to 150° C. The temperature of the heat to be supplied to the power generation element 1a is, for example, higher than or equal to 20° C.

The material of the first electrode 11 is not limited to a specific material so long as it can split water. The first electrode 11 contains, for example, a predetermined metal or alloy. Examples of the predetermined metal or alloy include at least one selected from the group consisting of Pt, Ag, Pd, Ru, Au, Cu, Ni, Ti, Fe, Cr, Al, W, and Zn. In this case, the first electrode 11 can exhibit high catalytic activity for water splitting.

The first electrode 11 may contain a Au—Al alloy, a Pt—Ru alloy, or a Ag—Pd alloy. The shape, material, and method of formation of the first electrode 11 are not limited to a specific shape, material, and method, respectively. The first electrode 11 is obtained by, for example, forming a film of a paste containing a metal or alloy by printing or coating, and baking the film. The first electrode 11 may be formed by sputtering, thermal spraying, plating, or pressure bonding.

The first electrode 11 may contain a carbon material. In this case, the first electrode 11 can exhibit high catalytic activity for water splitting. Examples of the carbon material include three-dimensional crystalline carbon such as graphite, glassy carbon, nanocarbon such as carbon nanotubes, amorphous carbon such as carbon black, activated carbon, and carbon fiber, and composite materials containing these carbon materials.

The material of the second electrode 12 is not limited to a specific material. As described above, the material of the second electrode 12 may be the same as or different from the material of the first electrode 11. The material of the second electrode 12 may contain, for example, a predetermined metal or alloy. Examples of the predetermined metal or alloy include at least one selected from the group consisting of Pt, Ag, Pd, Ru, Au, Cu, Ni, Ti, Fe, Cr, Al, W, and Zn.

The second electrode 12 may contain a Au—Al alloy, a Pt—Ru alloy, or a Ag—Pd alloy. The shape, material, and method of formation of the second electrode 12 are not limited to a specific shape, material, and method, respectively. The second electrode 12 is obtained by, for example, forming a film of a paste containing a metal or alloy by printing or coating, and baking the film. The second electrode 12 may be formed by sputtering, thermal spraying, plating, or pressure bonding.

The second electrode 12 may contain a carbon material. Examples of the carbon material include three-dimensional crystalline carbon such as graphite, glassy carbon, nanocarbon such as carbon nanotubes, amorphous carbon such as carbon black, activated carbon, and carbon fiber, and composite materials containing these carbon materials.

Ionic conductivity o of the inorganic solid electrolyte 15 is not limited to a specific value. The ionic conductivity σ satisfies, for example, a condition σ≥10⁻⁵ Scm⁻¹ at a temperature lower than or equal to 500° C. The ionic conductivity σ is ionic conductivity for ions generated by the splitting of water and conducted through the inorganic solid electrolyte 15. When such a condition is satisfied, the amount of power generated in the power generation element 1a tends to increase. For example, the inorganic solid electrolyte 15 satisfies the condition σ≥10⁻⁵ Scm⁻¹ at a temperature higher than or equal to 20° C. For example, the inorganic solid electrolyte 15 may satisfy the condition σ≥10⁻⁵ Scm⁻¹ at a temperature lower than or equal to 400° C., satisfy the condition σ≥10⁻⁵ Scm⁻¹ at a temperature lower than or equal to 300° C., or satisfy the condition σ≥10⁻⁵ Scm⁻¹ at a temperature lower than or equal to 200° C.

The material of the inorganic solid electrolyte 15 is not limited to a specific material so long as ions generated by the splitting of water are conducted through the inorganic solid electrolyte 15 and it contains at least one selected from the group consisting of a water molecule and a hydroxide ion. The inorganic solid electrolyte 15 may be, for example, a mineral. The mineral may be a natural mineral or an artificial mineral. The inorganic solid electrolyte 15 contains, for example, at least one selected from the group consisting of an oxide mineral, a carbonate mineral, a phosphate mineral, and a silicate mineral. In this case, the ionic conductivity of the inorganic solid electrolyte 15 tends to become higher. In addition, even when heat is supplied to the power generation element 1a, the power generation element 1a tends to have high durability, and the power generation element 1a has fewer restrictions on use.

Each of the oxide mineral, the carbonate mineral, the phosphate mineral, and the silicate mineral contained in the inorganic solid electrolyte 15 is not limited to a specific mineral. Examples of the oxide mineral include silica gel. In the present specification, artificially synthesized solids having compositions of oxides of silicon, such as silica gel, are classified into the oxide mineral. The basic composition of silica gel is SiO₂·H₂O. Examples of the carbonate mineral include hydrotalcite. The basic composition of hydrotalcite is Mg₆Al₂(OH)₁₆CO₃·4 H₂O. Examples of the phosphate mineral include apatite. The basic composition of apatite is Ca₁₀(PO₄)₆(OH)₂. Examples of the silicate mineral include smectite, kaolinite, zeolite F-9, and zeolite A-4. Smectite is a swellable silicate mineral. The basic crystal structure of smectite is a structure in which a tetrahedral sheet in which tetrahedrons of (Si,Al)O₄ are two-dimensionally bonded to each other and an octahedral sheet in which octahedrons of M(O,OH)₆ are connected to each other two-dimensionally in a mesh pattern share oxide ions. (Si,Al) means that at least one selected from the group consisting of Si and Al is contained, and (O,OH) means that at least one selected from the group consisting of O and OH is contained. Examples of M in the octahedral sheet include Al, Mg, Fe, and Ti. Smectite has a layered crystal structure formed of these two kinds of sheets combined. Smectite may be saponite, hectorite, stevensite, or montmorillonite. The basic composition of saponite is (Ca_{0.5},Na)_{0.33}Mg₃(Si_{3.67}A_{10.33})O₁₀(OH)₂. The basic composition of stevensite is (Ca_{0.5},Na)_{0.3}(Mg,Fe)₃Si₄O₁₀(OH)₂. The basic composition of montmorillonite is (Ca_{0.5},Na)_{0.33}(Al_{1.67}Mg_{0.33})Si₄O₁₀(OH)₂. The basic composition of kaolinite is Al₄Si₄O₁₀(OH)₈. The basic composition of zeolite F-9 is Na₈₆[(AlO₂)₈₆(SiO₂)₁₀₆]·x H₂O. The basic composition of zeolite A-4 is Na₁₂[(AlO₂)₁₂(SiO₂)₂]·y H₂O.

The inorganic solid electrolyte 15 may be a material having a layered crystal structure. In this case, hydration tends to occur in the inorganic solid electrolyte 15, and the ionic conductivity of the inorganic solid electrolyte 15 tends to become higher. For example, in smectite, cations are present between layers, and these cations exhibit very high water adsorptivity. This allows the ionic conductivity of the inorganic solid electrolyte 15 to be higher.

As illustrated in FIG. 1, the power generation element 1a includes a terminal 17. The terminal 17 is a terminal through which electric energy is supplied outside the power generation element 1a. For example, when an external circuit is electrically connected to the terminal 17, the power generation element 1a can supply electric energy to the external circuit.

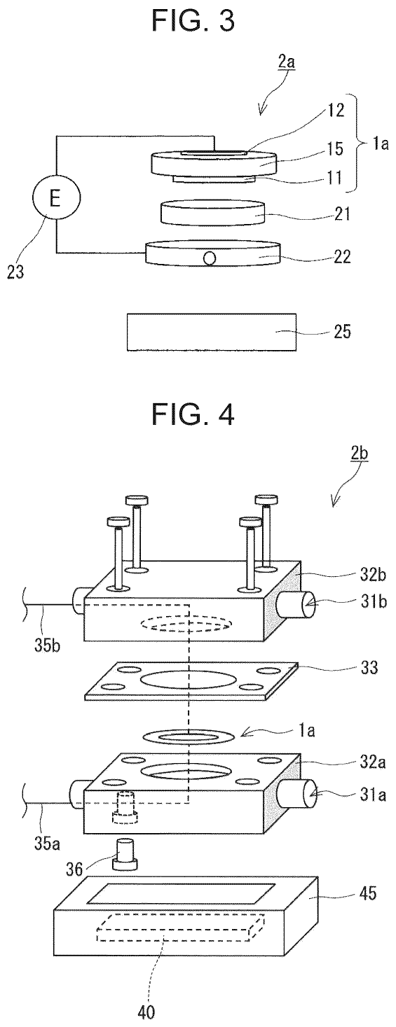

FIG. 3 is an exploded perspective view schematically illustrating an example of a power generation apparatus of the present disclosure. As illustrated in FIG. 3, a power generation apparatus 2a includes the power generation element 1a and an adsorber/desorber 21. The adsorber/desorber 21 communicates with a space around the first electrode 11 and adsorbs or desorbs water vapor depending on temperature. In the power generation apparatus 2a, the power generation element 1a can generate power as water is supplied from the adsorber/desorber 21, for example, even when the power generation element 1a is disposed in an enclosed space. In the power generation apparatus 2a, for example, the adsorber/desorber 21 contains a predetermined amount of water.

The adsorber/desorber 21 is, for example, disposed in contact with the first electrode 11. The first electrode 11 is, for example, disposed between the inorganic solid electrolyte 15 and the adsorber/desorber 21. The adsorber/desorber 21 may be disposed apart from the first electrode 11, and another member may be disposed between the adsorber/desorber 21 and the first electrode 11.

The material of the adsorber/desorber 21 is not limited to a specific material so long as it can adsorb or desorb water vapor depending on temperature. The adsorber/desorber 21 includes, for example, at least one selected from the group consisting of silica gel, a layered double hydroxide, a phosphoric acid hydrate, zeolite, metal felt, and a metal porous body. This enables the adsorber/desorber 21 to exhibit desired adsorbing and desorbing characteristics for water vapor. The metal felt is felt formed of metal fiber, and examples of the metal felt include nickel felt. Examples of the metal porous body include foamed nickel.

As illustrated in FIG. 3, the power generation apparatus 2a further includes, for example, a cap 22. The cap 22 can house therein the power generation element 1a and the adsorber/desorber 21. The cap 22 is, for example, formed of metal such as stainless steel, and is electrically connected to the first electrode 11. For example, by electrically connecting the cap 22 and the second electrode 12 to a predetermined measurement apparatus 23, an electromotive force and a current generated in the power generation apparatus 2a can be measured.

As illustrated in FIG. 3, heat from a heat source 25 is supplied to the power generation apparatus 2a. This enables the power generation apparatus 2a to easily generate a high electromotive force.

FIG. 4 is an exploded perspective view schematically illustrating another example of the power generation apparatus of the present disclosure. As illustrated in FIG. 4, a power generation apparatus 2b includes the power generation element 1a and a first supply path 31a. The first supply path 31a is a channel that guides a first fluid containing water to the first electrode 11. The first electrode 11 splits the water contained in the first fluid. With this configuration, the water contained in the first fluid is split at the first electrode 11, thereby causing the power generation element 1a to generate electric energy. The first supply path 31a is, for example, formed so as to adjoin the first electrode 11. The first fluid does not contain any gas used as a fuel gas in fuel cells, such as hydrogen gas.

The power generation apparatus 2b further includes, for example, a second supply path 31b. The second supply path 31b guides, for example, a second fluid containing water to the second electrode 12. Also with this configuration, electric energy can be generated in the power generation element 1a. The second supply path 31b is, for example, formed so as to adjoin the second electrode 12.

In the power generation apparatus 2b, the first fluid has, for example, a first water vapor pressure. The second fluid has, for example, a second water vapor pressure. The first water vapor pressure is different from the second water vapor pressure. For example, the first water vapor pressure is higher than the second water vapor pressure. In other words, the concentration of water vapor in the first fluid is higher than the concentration of water vapor in the second fluid. Thus, the concentration of protons generated at the first electrode 11 is higher than the concentration of protons generated at the second electrode 12, and electric energy can be generated in the power generation element 1a.

As illustrated in FIG. 4, the power generation apparatus 2b includes a channel member 32a, a channel member 32b, and a heat-resistant insulating sheet 33. The first supply path 31a is formed inside the channel member 32a, and the second supply path 31b is formed inside the channel member 32b. The heat-resistant insulating sheet 33 and the power generation element 1a are disposed between the channel member 32a and the channel member 32b. An opening is formed on the surface of the channel member 32a close to the power generation element 1a, thus allowing the first fluid passing through the first supply path 31a to come into contact with the first electrode 11 of the power generation element 1a. An opening is formed on the surface of the channel member 32b close to the power generation element 1a, thus allowing the second fluid passing through the second supply path 31b to come into contact with the second electrode 12 of the power generation element 1a. The heat-resistant insulating sheet 33 has heat resistance and electrically insulating properties. An opening adjoining the power generation element 1a is formed at the center of the heat-resistant insulating sheet 33.

The power generation apparatus 2b includes, for example, a lead 35a and a lead 35b. The lead 35a is connected to the first electrode 11, and the lead 35b is connected to the second electrode 12. Thus, the electric energy generated in the power generation element 1a is supplied to an external circuit.

The power generation apparatus 2b further includes, for example, a drain pipe 36. The drain pipe 36 is, for example, attached to the channel member 32a. Water generated by condensation of water vapor in the channel member 32a passes through the drain pipe 36 and is discharged outside the power generation apparatus 2b.

As illustrated in FIG. 4, a heater 40 is disposed near the power generation apparatus 2b. The channel member 32a and the channel member 32b are maintained at a predetermined temperature by heat supplied from the heater 40. A heat insulator 45 is disposed around the heater 40.

In the power generation apparatus 2b, the second electrode 12 may be in contact with air. The heat from the heater 40 may be supplied from the first electrode 11 of the power generation element 1a, or the entire power generation element 1a may be uniformly heated.

### Appendix

The following techniques are disclosed by the above description.

### Technique 1

A power generation element including:

a first electrode that splits water;

a second electrode; and

an inorganic solid electrolyte that is disposed between the first electrode and the second electrode and through which ions generated by the splitting of water at the first electrode are conducted toward the second electrode,

wherein the inorganic solid electrolyte contains at least one selected from the group consisting of a water molecule and a hydroxide ion.

### Technique 2

The power generation element according to Technique 1, wherein the inorganic solid electrolyte contains at least one selected from the group consisting of an oxide mineral, a carbonate mineral, a phosphate mineral, and a silicate mineral.

### Technique 3

The power generation element according to Technique 1 or 2, wherein the inorganic solid electrolyte has a layered crystal structure.

### Technique 4

The power generation element according to any one of Techniques 1 to 3, wherein the inorganic solid electrolyte has ionic conductivity for one kind of ion selected from the group consisting of a proton, an oxide ion, a hydronium ion, and a hydroxide ion.

### Technique 5

The power generation element according to any one of Techniques 1 to 4, wherein the inorganic solid electrolyte satisfies a condition σ≥10⁻⁵ Scm⁻¹ at a temperature lower than or equal to 500° C., where σ is ionic conductivity for the ions in the inorganic solid electrolyte.

### Technique 6

The power generation element according to any one of Techniques 1 to 5, wherein a material of the second electrode is different from a material of the first electrode.

### Technique 7

The power generation element according to any one of Techniques 1 to 6, wherein the first electrode contains a metal or alloy containing at least one selected from the group consisting of Pt, Ag, Pd, Ru, Au, Cu, Ni, Ti, Fe, Cr, Al, W, and Zn.

### Technique 8

The power generation element according to any one of Techniques 1 to 6, wherein the first electrode contains a carbon material.

### Technique 9

The power generation element according to any one of Techniques 1 to 8, wherein the first electrode is configured to come into contact with a fluid containing water present outside the power generation element.

### Technique 10

The power generation element according to any one of Techniques 1 to 9, further including a terminal through which electric energy is supplied outside the power generation element.

Technique 11

A power generation apparatus including:

the power generation element according to any one of Techniques 1 to 10; and

a first supply path that guides a first fluid containing water to the first electrode,

wherein the first electrode splits the water contained in the first fluid.

Technique 12

The power generation apparatus according to Technique 11, further including a second supply path that guides a second fluid containing water to the second electrode,

wherein the second electrode is configured to come into contact with the second fluid.

### Technique 13

The power generation apparatus according to Technique 12, wherein

the first fluid has a first water vapor pressure,

the second fluid has a second water vapor pressure, and

the first water vapor pressure is different from the second water vapor pressure.

### Technique 14

A power generation apparatus including:

the power generation element according to any one of Techniques 1 to 13; and

an adsorber/desorber that communicates with a space around the first electrode and that adsorbs or desorbs water vapor depending on temperature.

### Technique 15

The power generation apparatus according to Technique 14, wherein the adsorber/desorber includes at least one selected from the group consisting of silica gel, a layered double hydroxide, a phosphoric acid hydrate, zeolite, metal felt, and a metal porous body.

### Technique 16

A power generation method including:

placing a power generation element in an environment in which water is present to split water by a first electrode and generate ions, the power generation element including the first electrode, a second electrode, and an inorganic solid electrolyte disposed between the first electrode and the second electrode and containing at least one selected from the group consisting of a water molecule and a hydroxide ion;

conducting the ions toward the second electrode in the inorganic solid electrolyte;

oxidizing or reducing the ions at the second electrode to generate water; and

generating a current outside the power generation element.

### EXAMPLES

The present disclosure will be described below in detail with reference to examples. However, the power generation element and the power generation method of the present disclosure are not limited to specific aspects shown below. Measurement of Ionic Conductivity of Solid Electrolyte

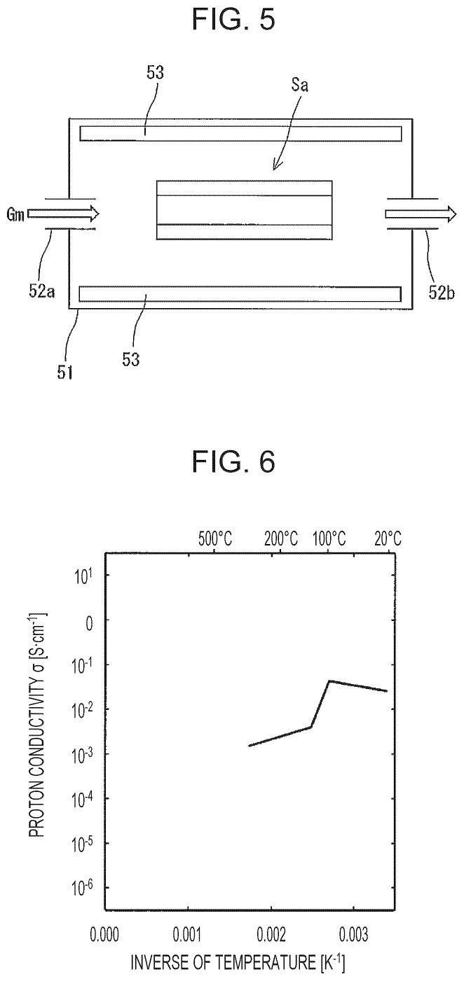

Saponite manufactured by Kunimine Industries Co., Ltd., Smecton-SA, was pressurized in a die having an inner diameter of 10 mm using a hydraulic press. In this pressurization, a pair of Ag electrodes having a diameter of 10 mm were disposed such that the saponite was positioned between the pair of Ag electrodes, and the Ag electrodes were attached to both surfaces of the saponite to obtain a pellet with electrodes. Saponite is a kind of smectite. The obtained pellet with electrodes was disposed inside a cell 51 illustrated in FIG. 5. The cell 51 had an inlet 52a and an outlet 52b, the inlet 52a was connected to a bubbler (not shown) set at 80° C., and air Gm containing water vapor was supplied from this bubbler inside the cell 51. The gas flowed along both surfaces of the pellet with electrodes inside the cell 51, and was discharged outside the cell 51 from the outlet 52b. Heaters 53 were disposed inside the cell 51, and the temperature inside the cell 51 was adjusted such that the spaces adjoining both electrodes of a sample Sa had an equal temperature. While the temperature inside the cell 51 was changed from 25° C. to 300° C., impedance measurement was performed on the pellet with electrodes in a frequency range of 4 to 8 MHz to determine the proton conductivity of the saponite. For the impedance measurement, an LCR meter IH 3536 manufactured by Hioki E.E. Corporation was used. FIG. 6 illustrates the results. As illustrated in FIG. 6, the saponite showed a high proton conductivity of greater than or equal to 10⁻⁵ Scm⁻¹ in the range of room temperature to 300° C.

### Samples A-1 to A-5

Power generation elements according to Samples A-1 to A-5 were produced in the same manner as in the production of the pellet with electrodes except that the electrodes attached to both surfaces of the saponite were changed to the combinations listed in Table 1. The Pt electrode was obtained by drying a coating film formed by applying a Pt-containing paste onto a substrate formed of Cu or Ti.

TABLE 1

| | | Range of | Temperature at | Temperature at which |
|---|---|---|---|---|
| | | electromotive | which electromotive | highest electromotive |
| | Configuration of | force generated | force was generated | force was generated |
| | element | [mV] | [° C.] | [° C.] |
| A-1 | Cu/saponite/Ag | 37-405 | 23-220 | 23 |
| A-2 | Cu/saponite/Pt_{(on Cu)} | 15-235 | 25-130 | 50 |
| A-3 | Cu/saponite/SUS316 | 13-141 | 25-200 | 130 |
| A-4 | Cu/saponite/Pt_{(on Ti)} | 15-220 | 25-230 | 100 |
| A-5 | Ti/saponite/Ag | 117-359 | 25-300 | 200 |

### REFERENCE EXAMPLES

Samples according to Reference Examples 1 and 2 were obtained in the same manner as in the production of the pellet with electrodes while using Cu electrodes and Ag electrodes, respectively, as the electrodes attached to both surfaces of the saponite. Evaluation of Electromotive Force

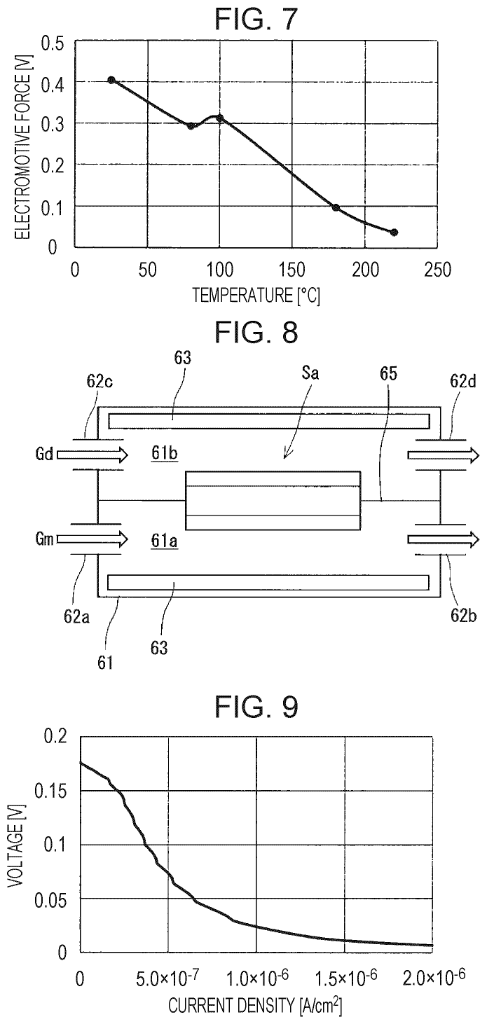

Each of Samples A-1 to A-5 and the samples Sa according to Reference Examples 1 and 2 was disposed inside the cell 51, and the temperature inside the cell 51 was changed from room temperature to 300° C. while air Gm containing water vapor was supplied inside the cell 51. Note that the temperature inside the cell 51 was adjusted such that the spaces adjoining both electrodes of each sample Sa had an equal temperature. Under such conditions, an electromotive force generated between both electrodes of each sample was measured. Table 1 lists the results. In addition, FIG. 7 illustrates the relation between the electromotive force of the power generation element according to Sample A-1 and the temperature.

In Samples A-1 to A-5, which had different kinds of electrodes attached to both surfaces of the saponite, the generation of the electromotive force was observed. In the samples according to Reference Examples 1 and 2, which had the same kind of electrodes attached to both surfaces of the saponite, on the other hand, the generation of the electromotive force was not observed.

### Samples A-6 to A-13

Power generation elements according to Samples A-6 to A-13 were produced in the same manner as in the production of the pellet with electrodes except for the following points. In place of the saponite, the inorganic substances listed in Table 2 were used. A Pt electrode was used as one of the electrodes attached to both surfaces of the saponite, and a Cu electrode was used as the other electrode. As with Sample A-1, an electromotive force generated between both electrodes of each sample was measured. Table 2 lists the results. As shown in Table 2, it was observed that the electromotive force was generated in the power generation elements using the inorganic substances other than the saponite.

TABLE 2

| | | Range of | Temperature at | Temperature at which |
|---|---|---|---|---|
| | | electromotive | which electromotive | highest electromotive |
| | Inorganic solid | force generated | force was generated | force was generated |
| | electrolyte | [mV] | [° C.] | [° C.] |
| A-6 | Stevensite | 146-289 | 25-300 | 270 |
| A-7 | Montmorillonite | 98-349 | 25-300 | 130 |
| A-8 | Kaolinite | 124-343 | 25-200 | 80 |
| A-9 | Hydrotalcite | 136-225 | 25-200 | 80 |
| A-10 | Zeolite F-9 | 73-218 | 21-300 | 21 |
| A-11 | Zeolite A-4 | 184-306 | 27-300 | 300 |
| A-12 | Apatite HAP | 106-222 | 28-130 | 80 |
| A-13 | Silica gel | 162-261 | 28-170 | 170 |

### Samples A-14 to A-30

Power generation elements according to Samples A-14 to A-30 were produced in the same manner as in the production of the pellet with electrodes except for the following points. In place of the saponite, montmorillonite was used. The electrodes attached to both surfaces of the montmorillonite were changed to the combinations listed in Table 3. In Table 3, Cu—Pt is an electrode in which Pt was supported on Cu, and was obtained by applying a Pt nanodispersion onto Cu and drying it at 120° C. Carbon is glassy carbon, and carbon-Pt is an electrode in which Pt was supported on carbon, and was obtained by applying a Pt nanodispersion onto Cu and drying it at 120° C. as with Cu—Pt. Cu—Zn is an alloy of Cu and Zn (brass). As with Sample A-1, an electromotive force generated between both electrodes of each sample was measured at 30° C. Table 3 lists the results.

TABLE 3

| | | Electromotive force |
|---|---|---|
| | Configuration of element | generated at 30° C. [mV] |
| A-14 | Cu/montmorillonite/Pt | 260 |
| A-15 | Cu—Pt/montmorillonite/Pt | 240 |
| A-16 | Ti/montmorillonite/Pt | 140 |
| A-17 | Ni/montmorillonite/Pt | 200 |
| A-18 | SUS310/montmorillonite/Pt | 70 |
| A-19 | Cu/montmorillonite/carbon | 180 |
| A-20 | Cu/montmorillonite/carbon-Pt | 270 |
| A-21 | Cu/montmorillonite/SUS310 | 170 |
| A-22 | Al/montmorillonite/Pt | 450 |
| A-23 | Al—Pt/montmorillonite/Pt | 720 |
| A-24 | Cu—Pt/montmorillonite/carbon | 30 |
| A-25 | SUS310/montmorillonite/carbon | 80 |
| A-26 | Cu—Pt/montmorillonite/Cu | 30 |
| A-27 | Al/montmorillonite/Cu | 340 |
| A-28 | Ni/montmorillonite/Cu | 70 |
| A-29 | Al/montmorillonite/Ni | 150 |
| A-30 | Cu—Zn/montmorillonite/Pt | 300 |

### Sample B-1

A power generation element according to Sample B-1 was obtained in the same manner as in the production of the pellet with electrodes except that Cu electrodes were used as the electrodes attached to both surfaces of the saponite.

### Sample B-2

Saponite alone was pressurized with a hydraulic press to produce a pellet. A Pt-containing paste manufactured by Tanaka Precious Metal Technologies Co., Ltd. was applied to both surfaces of this pellet, and the coating film of the Pt-containing paste was dried at 130° C. to obtain a power generation element according to Sample B-2.

### Sample B-3

A Pt-containing paste was applied to stainless steel nets, and the stainless steel nets were heated to 900° C. to obtain a pair of electrodes. In a state where the thus-obtained pair of electrodes were disposed such that the saponite was disposed between the pair of electrodes, pressurization using a hydraulic press was performed to obtain a power generation element according to Sample B-3.

### Evaluation of Electromotive Force

The electromotive force of the power generation elements according to Samples B-1 to B-3 was evaluated as follows. The power generation elements according to Samples B-1 to B-3 were each disposed inside a cell 61 illustrated in FIG. 8. A partition 65 partitioning the inside of the cell 61 into a space 61a and a space 61b was disposed inside the cell 61. An opening for disposing each sample was formed at the center of the partition 65. Each sample Sa was fixed so as to block this opening. The cell 61 had a first inlet 62a, a first outlet 62b, a second inlet 62c, and a second outlet 62d. The first inlet 62a and the first outlet 62b adjoined the space 61a, and the second inlet 62c and the second outlet 62d adjoined the space 61b. The first inlet 62a was connected to a bubbler (not shown) adjusted to 80° C., and air Gm containing water vapor was supplied to the space 61a through the first inlet 62a. The air Gm passed through the space 61a, and was then discharged from the first outlet 62b. Dried air Gd was supplied to the space 61b through the second inlet 62c. The dried air Gd passed through the space 61b, and was then discharged from the second outlet 62d. Heaters 63 were disposed inside the cell 61, and the temperature inside the cell 61 was adjusted to 70° C. Under such conditions, an electromotive force generated between the electrodes of each power generation element was measured. Consequently, the generation of the electromotive force was observed in the power generation elements according to Samples B-1 to B-3.

### Power Generation Characteristics

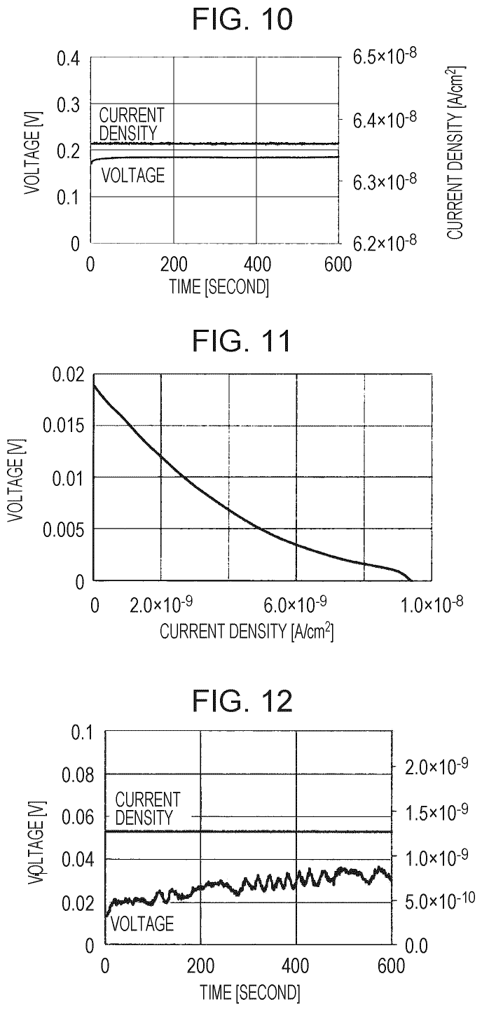

FIG. 9 illustrates the I-V characteristics of the power generation element according to Sample A-1. The vertical axis of FIG. 9 indicates voltage, and the horizontal axis indicates current density. FIG. 10 is a graph of the continuous discharge characteristics of the power generation element according to Sample A-1. The vertical axis of FIG. 10 indicates voltage or current density, and the horizontal axis indicates time. FIG. 10 illustrates a change in voltage when a current load of 0.05 μA continued to be applied. As illustrated in FIG. 10, it was shown that when the electromotive force was generated, the current load was able to be applied, and so long as heat continued to be given to the power generation element, electricity was taken out of the power generation element. In addition, a current was also continuously taken out by using the power generation elements according to Samples A-2 to A-30.

FIG. 11 is a graph of the I-V characteristics of the power generation element according to Sample B-3. FIG. 11 was measured under the conditions in which the temperature of the cell was kept at 70° C. and gas Gm containing water vapor flowed along the anode. The vertical axis of FIG. 11 indicates voltage, and the horizontal axis indicates current density. FIG. 12 is a graph of the continuous discharge characteristics of the power generation element according to Sample B-3. The vertical axis of FIG. 12 indicates voltage or current density, and the horizontal axis indicates time. FIG. 12 illustrates a change in voltage in a state where a current load of 1×10⁻³ μA continued to be applied. As illustrated in FIG. 12, it was shown that so long as there was a difference in water concentration between both electrodes of the power generation element, electricity was taken out of the power generation element. In addition, a current was also continuously taken out by using the power generation elements according to Samples B-1 and B-2.

The power generation element of the present disclosure can be used in various applications including the applications of power generation elements in the related art.

What is claimed is:

1. A power generation element comprising:
a first electrode that splits water;
a second electrode; and
an inorganic solid electrolyte that is disposed between the first electrode and the second electrode and through which ions generated by the splitting of water at the first electrode are conducted toward the second electrode,
wherein
catalytic activity of the first electrode with respect to water splitting at a predetermined temperature is higher than catalytic activity of the second electrode with respect to water splitting at a predetermined temperature; and
the inorganic solid electrolyte contains at least one selected from the group consisting of a water molecule and a hydroxide ion.

2. The power generation element according to claim 1, wherein the inorganic solid electrolyte contains at least one selected from the group consisting of an oxide mineral, a carbonate mineral, a phosphate mineral, and a silicate mineral.

3. The power generation element according to claim 1, wherein the inorganic solid electrolyte has a layered crystal structure.

4. The power generation element according to claim 1, wherein the inorganic solid electrolyte has ionic conductivity for one kind of ion selected from the group consisting of a proton, an oxide ion, a hydronium ion, and a hydroxide ion.

5. The power generation element according to claim 1, wherein the inorganic solid electrolyte satisfies a condition σ≥10⁻⁵ Scm⁻¹ at a temperature lower than or equal to 500° C., where σ is ionic conductivity for the ions in the inorganic solid electrolyte.

6. The power generation element according to claim 1, wherein the first electrode contains a metal or alloy containing at least one selected from the group consisting of Pt, Ag, Pd, Ru, Au, Cu, Ni, Ti, Fe, Cr, Al, W, and Zn.

7. The power generation element according to claim 1, wherein the first electrode contains a carbon material.

8. The power generation element according to claim 1, wherein the first electrode is configured to come into contact with a fluid containing water present outside the power generation element.

9. The power generation element according to claim 1, further comprising a terminal through which electric energy is supplied outside the power generation element.

10. A power generation apparatus comprising:
the power generation element according to claim 1; and
a first supply path that guides a first fluid containing water to the first electrode,
wherein the first electrode splits the water contained in the first fluid.

11. The power generation apparatus according to claim 10, further comprising a second supply path that guides a second fluid containing water to the second electrode,
wherein the second electrode is configured to come into contact with the second fluid.

12. The power generation apparatus according to claim 11, wherein
the first fluid has a first water vapor pressure,
the second fluid has a second water vapor pressure, and
the first water vapor pressure is different from the second water vapor pressure.

13. A power generation apparatus comprising:
the power generation element according to claim 1; and
an adsorber/desorber that communicates with a space around the first electrode and that adsorbs or desorbs water vapor depending on temperature.

14. The power generation apparatus according to claim 13, wherein the adsorber/desorber includes at least one selected from the group consisting of silica gel, a layered double hydroxide, a phosphoric acid hydrate, zeolite, metal felt, and a metal porous body.

15. A power generation method comprising:
placing a power generation element in an environment in which water is present to split water by a first electrode and generate ions, the power generation element including the first electrode, a second electrode, and an inorganic solid electrolyte disposed between the first electrode and the second electrode and containing at least one selected from the group consisting of a water molecule and a hydroxide ion;
conducting the ions toward the second electrode in the inorganic solid electrolyte;
oxidizing or reducing the ions at the second electrode to generate water; and
generating a current outside the power generation element.
